(19) United States
(12) Patent Application Publication
(10) Pub. No.: US 2025/0132218 A1
(43) Pub. Date: Apr. 24, 2025

(54) SEMICONDUCTOR PACKAGE

(71) Applicant: SAMSUNG ELECTRONICS CO., LTD., Suwon-si (KR)

(72) Inventors: KYUNG DON MUN, Suwon-si (KR); WOOYOUNG KIM, Suwon-si (KR); YEONHO JANG, Suwon-si (KR); HYEONJEONG HWANG, Suwon-si (KR)

(73) Assignee: SAMSUNG ELECTRONICS CO., LTD., Suwon-si (KR)

(21) Appl. No.: 18/623,488

(22) Filed: Apr. 1, 2024

(30) Foreign Application Priority Data
Oct. 18, 2023 (KR) 10-2023-0139463

(51) Int. Cl. H01L 23/367; H01L 23/00; H01L 23/31; H01L 23/373; H01L 25/00; H01L 25/18

(52) U.S. Cl. CPC H01L 23/367; H01L 23/3128; H01L 23/3736; H01L 25/18; H01L 25/50; H01L 24/16; H01L 24/80; H01L 2224/16225; H01L 2224/808; H01L 2924/1431; H01L 2924/1437

(57) ABSTRACT

A semiconductor package includes: a first substrate; a first semiconductor chip; a second semiconductor chip being spaced apart, in a first direction, from the first substrate, the first direction being parallel to a top surface of the first substrate; at least one thermal radiation structure on the first substrate and between the first semiconductor chip and the second semiconductor chip; and a third semiconductor chip on the first semiconductor chip, the second semiconductor chip, and the at least one thermal radiation structure, wherein the at least one thermal radiation structure includes: a thermal radiation post; and a thermal conductive pattern on the thermal radiation post, wherein a bottom surface of the third semiconductor chip is in contact with the thermal conductive pattern, and wherein the top surface of the first substrate is in contact with the thermal radiation post.

### CROSS-REFERENCE TO RELATED APPLICATION

This application is based on and claims priority under 35 U.S.C § 119 to Korean Patent Application No. 10-2023-0139463, filed on Oct. 18, 2023, in the Korean Intellectual Property Office, the disclosure of which is hereby incorporated by reference in its entirety.

### BACKGROUND

### 1. Field

The disclosure relates to a semiconductor package, and more particularly, to a semiconductor package including a thermal radiation structure.

### 2. Description of Related Art

Portable devices have been increasingly demanded in recent electronic product markets, and as a result, reduction in size and weight of electronic parts (mounted on the portable devices) have been required. In order to accomplish the reduction in size and weight of the electronic parts, technologies have been proposed or developed to integrate a number of individual devices into a single package as well as technology to reduce individual sizes of mounting parts. In particular, a semiconductor package (in which a plurality of devices are integrated) needs to have a compact size, improved thermal characteristics, and excellent electrical properties.

### SUMMARY

Provided are a semiconductor package with increased thermal radiation efficiency and a method of fabricating the semiconductor package.

An aspect of the disclosure is not limited to the mentioned above, and other objects which have not been mentioned above will be clearly understood to those skilled in the art from the following description.

According to an aspect of the disclosure, a semiconductor package includes: a first substrate; a first semiconductor chip on the first substrate; a second semiconductor chip on the first substrate, the second semiconductor chip being spaced apart, in a first direction, from the first substrate, the first direction being parallel to a top surface of the first substrate; at least one thermal radiation structure on the first substrate and between the first semiconductor chip and the second semiconductor chip; and a third semiconductor chip on the first semiconductor chip, the second semiconductor chip, and the at least one thermal radiation structure, wherein the at least one thermal radiation structure includes: a thermal radiation post; and a thermal conductive pattern on the thermal radiation post, wherein a bottom surface of the third semiconductor chip is in contact with the thermal conductive pattern, and wherein the top surface of the first substrate is in contact with the thermal radiation post.

According to an aspect of the disclosure, a semiconductor package includes: a first substrate; a first semiconductor chip on the first substrate; a second semiconductor chip on the first substrate, the second semiconductor chip being spaced apart in a first direction from the first semiconductor chip, the first direction being parallel to a top surface of the first substrate; at least one thermal radiation structure on the first substrate and between the first semiconductor chip and the second semiconductor chip; and a third semiconductor chip on the first semiconductor chip, the second semiconductor chip, and the at least one thermal radiation structure, wherein the at least one thermal radiation structure includes: a thermal radiation post; and a thermal conductive pattern on the thermal radiation post, wherein the third semiconductor chip includes: a wiring layer; and a circuit layer on the wiring layer, wherein the thermal conductive pattern is in contact with the wiring layer, wherein the circuit layer includes a plurality of circuit regions, and wherein the at least one thermal radiation structure overlaps, in a second direction, with at least one of the plurality of circuit regions, the second direction being perpendicular to the top surface of the first substrate.

According to an aspect of the disclosure, a semiconductor package includes: a first redistribution substrate; a second redistribution substrate on the first redistribution substrate; a first semiconductor chip on the first redistribution substrate; a second semiconductor chip on the first redistribution substrate, the second semiconductor chip being spaced apart, in a first direction, from the first semiconductor chip, the first direction being parallel to a top surface of the first redistribution substrate; a third semiconductor chip on the first semiconductor chip and the second semiconductor chip, a portion of a bottom surface of the third semiconductor chip being in contact with a portion of a top surface of the first semiconductor chip and a portion of a top surface of the second semiconductor chip; and at least one thermal radiation structure below the third semiconductor chip, the at least one thermal radiation structure being between the first semiconductor chip and the second semiconductor chip, wherein the third semiconductor chip includes: a wiring layer; and a circuit layer on the wiring layer, wherein the at least one thermal radiation structure includes: a thermal radiation post; and a thermal conductive pattern on the thermal radiation post, wherein the thermal conductive pattern is in contact with the wiring layer, wherein the circuit layer includes a plurality of circuit regions, and wherein the at least one thermal radiation structure overlaps, in a second direction, with at least one of the plurality of circuit regions, the second direction being perpendicular to the top surface of the first redistribution substrate.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1 illustrates a plan view showing a semiconductor package according to some embodiments of the disclosure;

FIG. 2 illustrates a cross-sectional view taken along line A-A′ of FIG. 1;

FIG. 3 illustrates an enlarged view showing section CU of FIG. 2;

FIG. 4 illustrates a cross-sectional view showing a semiconductor package according to some embodiments of the disclosure;

FIG. 5 illustrates a cross-sectional view showing a semiconductor package according to some embodiments of the disclosure;

FIG. 6 illustrates a cross-sectional view showing a semiconductor package according to some embodiments of the disclosure;

FIG. 7 illustrates a cross-sectional view showing a semiconductor package according to some embodiments of the disclosure;

FIGS. 8A to 8D illustrate cross-sectional views showing a method of fabricating a semiconductor device according to some embodiments of the disclosure; and

FIGS. 9A and 9B illustrate cross-sectional views partially showing a method of fabricating a semiconductor package according to some embodiments of the disclosure.

### DETAILED DESCRIPTION

The description merely illustrates the principles of the disclosure. Those skilled in the art will be able to devise one or more arrangements that, although not explicitly described herein, embody the principles of the disclosure. Furthermore, all examples recited herein are principally intended expressly to be only for explanatory purposes to help the reader in understanding the principles of the disclosure and the concepts contributed by the inventor to furthering the art and are to be construed as being without limitation to such specifically recited examples and conditions. Moreover, all statements herein reciting principles, aspects, and embodiments of the disclosure, as well as specific examples thereof, are intended to encompass equivalents thereof.

Terms used in the disclosure are used only to describe a specific embodiment, and may not be intended to limit the scope of another embodiment. A singular expression may include a plural expression unless it is clearly meant differently in the context. The terms used herein, including a technical or scientific term, may have the same meaning as generally understood by a person having ordinary knowledge in the technical field described in the present disclosure. Terms defined in a general dictionary among the terms used in the present disclosure may be interpreted with the same or similar meaning as a contextual meaning of related technology, and unless clearly defined in the present disclosure, it is not interpreted in an ideal or excessively formal meaning. In some cases, even terms defined in the disclosure cannot be interpreted to exclude embodiments of the present disclosure.

In one or more embodiments of the disclosure described below, a hardware approach is described as an example. However, since the one or more embodiments of the disclosure include technology that uses both hardware and software, the various embodiments of the present disclosure do not exclude a software-based approach.

In addition, in the disclosure, in order to determine whether a specific condition is satisfied or fulfilled, an expression of more than or less than may be used, but this is only a description for expressing an example, and does not exclude description of more than or equal to or less than or equal to. A condition described as ‘more than or equal to’ may be replaced with ‘more than’, a condition described as ‘less than or equal to’ may be replaced with ‘less than’, and a condition described as ‘more than or equal to and less than’ may be replaced with ‘more than and less than or equal to’. In addition, hereinafter, ‘A’ to ‘B’ means at least one of elements from A (including A) and to B (including B).

The terms “include” and “comprise”, and the derivatives thereof refer to inclusion without limitation. The term “or” is an inclusive term meaning “and/or”. The phrase “at least one of,” when used with a list of items, means that different combinations of one or more of the listed items may be used, and only one item in the list may be needed. For example, “at least one of A, B, and C” includes any of the following combinations: A, B, C, A and B, A and C, B and C, and A and B and C, and any variations thereof. The expression “at least one of a, b, or c” may indicate only a, only b, only c, both a and b, both a and c, both b and c, all of a, b, and c, or variations thereof. Similarly, the term “set” means one or more. Accordingly, the set of items may be a single item or a collection of two or more items.

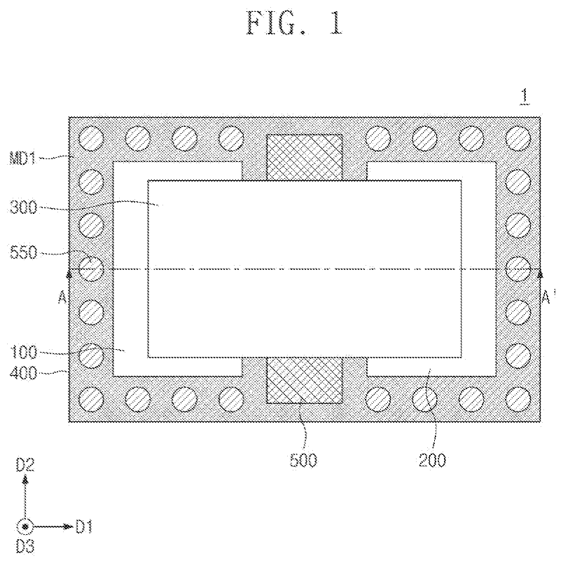

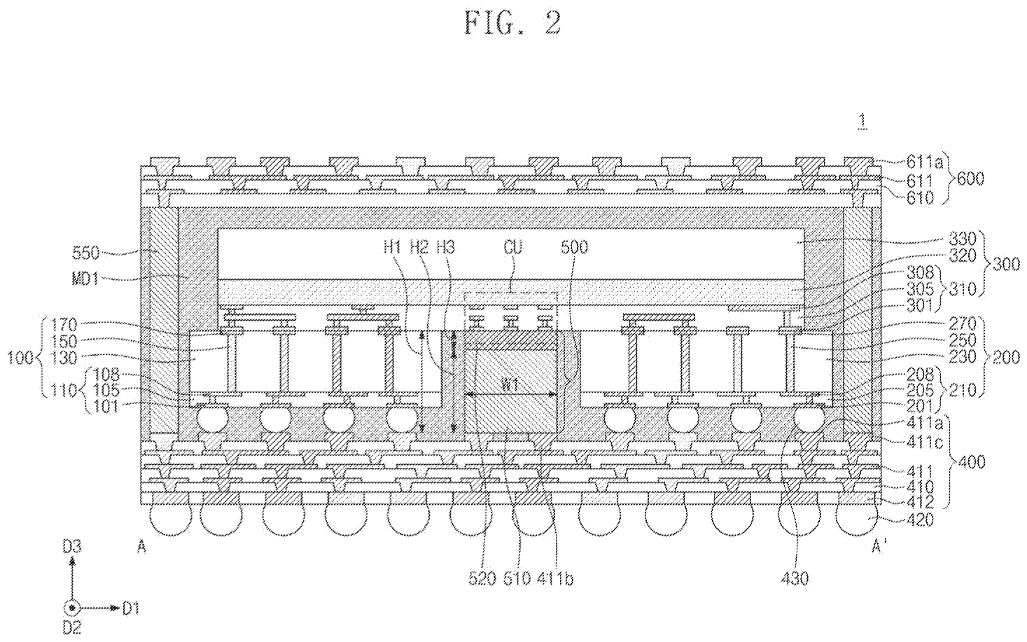

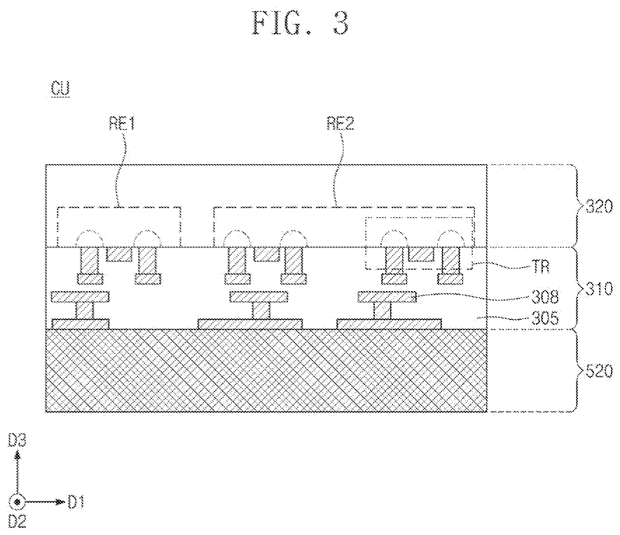

FIG. 1 illustrates a plan view showing a semiconductor package according to some embodiments of the disclosure. FIG. 2 illustrates a cross-sectional view taken along line A-A′ of FIG. 1. FIG. 3 illustrates an enlarged view showing section CU of FIG. 2.

Referring to FIGS. 1 to 3, a semiconductor package 1 according to some embodiments of the disclosure may include a first redistribution substrate 400 (e.g., a first substrate), a first semiconductor chip 100, a second semiconductor chip 200, a third semiconductor chip 300, and a thermal radiation structure 500. The first semiconductor chip 100, the second semiconductor chip 200, and the third semiconductor chip 300 may form a “chiplet” structure. In the disclosure, the term “chiplet” may refer to a device including independent chips that are functionally divided from an ordinary chip and are connected through one or more through vias.

The first redistribution substrate 400 may include a plurality of first dielectric layers 410 and a plurality of first redistribution patterns 411 that are stacked on each other. In the disclosure, a first direction D1 is defined to indicate one direction parallel to a top surface of the first redistribution substrate 400. A second direction D2 is defined to indicate one direction parallel to the top surface of the first redistribution substrate 400 and orthogonal to the first direction D1. A third direction D3 is defined to indicate one direction perpendicular to the top surface of the first redistribution substrate 400.

The first dielectric layers 410 may include an organic material, such as a photo-imageable dielectric (PID). The photo-imageable dielectric may be a polymer. The photo-imageable dielectric may include, for example, at least one selected from photosensitive polyimide, polybenzoxazole, phenolic polymers, and benzocyclobutene polymers. FIG. 2 shows a boundary between the first dielectric layers 410, but the disclosure are not limited thereto. According to some embodiments, an indistinct interface may be provided between neighboring first dielectric layers 410.

The first redistribution patterns 411 may be provided in the first dielectric layers 410. The first redistribution patterns 411 may each have a first via part and a first wiring part that are connected into a single unitary piece. The first wiring part may be a pattern for horizontal connection in the first redistribution substrate 400. The first via part may be a portion for vertical connection between the first redistribution patterns 411 in the first dielectric layers 410. The first wiring part may be provided on the first via part. In an embodiment, the first wiring part and the first via part may be directly connected with no interface therebetween. The first wiring parts of the first redistribution patterns 411 may be positioned on top surfaces of the first dielectric layers 410. The first via parts of the first redistribution patterns 411 may penetrate the first dielectric layers 410 to come into connection with the first wiring parts of underlying first redistribution patterns 411. The first redistribution patterns 411 may include a conductive material. For example, the first redistribution patterns 411 may include copper (Cu).

In an embodiment, seed patterns may be disposed on bottom surfaces of the first redistribution patterns 411. For example, the seed patterns may cover bottom surfaces and sidewalls of the first via parts and bottom surfaces of the first wiring parts of corresponding first redistribution patterns 411. The seed patterns may include a different material from that of the first redistribution patterns 411. For example, the seed patterns may include copper (Cu), titanium (Ti), or any alloy thereof. According to some embodiments, the first redistribution patterns 411 may further include a barrier layer that prevents diffusion of materials included in the first redistribution patterns 411. The barrier layer may include titanium nitride (TiN) or tantalum nitride (TaN).

The first redistribution patterns 411 may include a first redistribution pad 411a, a second redistribution pad 411b, and a third redistribution pad 411c. The first redistribution pad 411a, the second redistribution pad 411b, and the third redistribution pad 411c may be portions of the first redistribution pattern 411 disposed on an uppermost end of the first redistribution substrate 400. The first redistribution pad 411a, the second redistribution pad 411b, and the third redistribution pad 411c may have their top surfaces that protrude from the top surface of the first redistribution substrate 400. The first redistribution pad 411a, the second redistribution pad 411b, and the third redistribution pad 411c may be connected to underlying first redistribution patterns 411.

The first redistribution substrate 400 may be provided with under-bump patterns 412 on a bottom surface thereof. The under-bump patterns 412 may be spaced apart from each other in the first direction D1. The under-bump patterns 412 may be connected to the first redistribution patterns 411. For example, the first via part of a lowermost one of the first redistribution patterns 411 may penetrate the first dielectric layer 410 to come into connection with the under-bump pattern 412. The under-bump patterns 412 may be electrically connected through the first redistribution patterns 411 to the first redistribution pad 411a, the second redistribution pad 411b, and the third redistribution pad 411c. The under-bump patterns 412 may include a conductive material. For example, the under-bump patterns 412 may include copper (Cu).

The under-bump patterns 412 may be provided with external connection terminals 420 on bottom surfaces thereof. The external connection terminals 420 may be spaced apart from each other in the first direction D1. The external connection terminals 420 may include a solder material. For example, the external connection terminals 420 may include tin (Sn), bismuth (Bi), lead (Pb), silver (Ag), or any alloy thereof.

The first semiconductor chip 100 may be disposed on the top surface of the first redistribution substrate 400. The first semiconductor chip 100 may include a first wiring layer 110, a circuit layer, and a first semiconductor substrate 130 (on the first wiring layer 110). In the disclosure, the circuit layer may refer to a region or layer in which is formed an integrated circuit such as a transistor. The first wiring layer 110 may include a second dielectric layer 105, the first wiring lines 108, and first chip pads 101 disposed in the second dielectric layer 105. The first wiring lines 108 may include metal, such as copper or aluminum. In the first wiring layer 110, the first chip pads 101 may be disposed on a bottom surface of the first semiconductor chip 100. The first semiconductor substrate 130 (of the first semiconductor chip 100) may be, for example, a silicon substrate. The first semiconductor substrate 130 may include a first ‘through via’ 150 that penetrates the first semiconductor substrate 130 and a first connection pad 170 disposed on a top surface of the first semiconductor chip 100.

For example, the first semiconductor chip 100 may be a mobile chip or an analog chip. For example, the first semiconductor chip 100 may include one of a WiFi module chip, a Bluetooth module chip, a cellular module chip, a power management chip, an AC-DC converter, a motor driver chip, and a radio frequency chip. According to some embodiments, the first semiconductor chip 100 may include an L3 cache memory region.

The second semiconductor chip 200 may be disposed on the top surface of the first redistribution substrate 400. The second semiconductor chip 200 may be spaced apart (in the first direction D1) from the first semiconductor chip 100. The second semiconductor chip 200 may include a second wiring layer 210, a circuit layer, and a second semiconductor substrate 230 (on the second wiring layer 210). The second wiring layer 210 may include a third dielectric layer 205, second wiring lines 208, and second chip pads 201 (disposed in the third dielectric layer 205). The second wiring lines 208 may include metal, such as copper or aluminum. In the second wiring layer 210, the second chip pads 201 may be disposed on a bottom surface of the second semiconductor chip 200. The second semiconductor substrate 230 may be, for example, a silicon substrate. The second semiconductor substrate 230 may include a second ‘through via’ 250 that penetrates the second semiconductor substrate 230 and a second connection pad 270 disposed on a top surface of the second semiconductor chip 200.

For example, the second semiconductor chip 200 may be a mobile chip or an analog chip. For example, the second semiconductor chip 200 may include one of a WiFi module chip, a Bluetooth module chip, a cellular module chip, a power management chip, an AC-DC converter, a motor driver chip, and a radio frequency chip. According to some embodiments, the second semiconductor chip 200 may include an L3 cache memory region.

Connection terminals 430 may be disposed between the first redistribution substrate 400 and the first semiconductor chip 100. Connection terminals 430 may be disposed between the first redistribution substrate 400 and the second semiconductor chip 200. For example, the connection terminals 430 may be interposed between and in contact with the first redistribution pad 411a and the first chip pad 101. For example, the connection terminals 430 may also be interposed between and in contact with first the redistribution pad 411a and the second chip pad 201. The first semiconductor chip 100 and the second semiconductor chip 200 may be operatively or electrically connected, through the connection terminals 430, to the first redistribution substrate 400. The connection terminals 430 may include a metallic material substantially the same as or similar to that of the external connection terminals 420. For example, the connection terminals 430 may include tin (Sn), bismuth (Bi), lead (Pb), silver (Ag), or any alloy thereof.

The thermal radiation structure 500 may be disposed on the top surface of the first redistribution substrate 400. For example, the thermal radiation structure 500 may be disposed between the first semiconductor chip 100 and the second semiconductor chip 200, and may be spaced apart in the first direction D1 and/or the second direction D2 from the first semiconductor chip 100 and the second semiconductor chip 200. A bottom surface of the thermal radiation structure 500 may be in contact with the top surface of the second redistribution pad 411b. According to some embodiments, an adhesive material may be provided between the bottom surface of the thermal radiation structure 500 and the top surface of the second redistribution pad 411b.

The thermal radiation structure 500 may include a thermal radiation post 510 and the thermal conductive pattern 520. In an embodiment, the thermal conductive pattern 520 may be disposed on the thermal radiation post 510. For example, the thermal radiation post 510 may be adjacent to the first redistribution substrate 400 than to the second redistribution substrate 600 (e.g., a second substrate). In an embodiment, the thermal radiation structure 500 may have a first width “W1” in the first direction D1.

In an embodiment, the first width W1 may range from about 150 μm to about 250 μm. In an embodiment, a length in the second direction D2 of the thermal radiation structure 500 may be different that depicted in FIG. 1. For example, the length in the second direction D2 of the thermal radiation structure 500 may be shorter than a length in the second direction D2 of at least one of the first semiconductor chip 100 and the second semiconductor chip 200.

The thermal radiation structure 500 may have a first height H1 in the third direction D3. In an embodiment, the first height H1 may range from about 160 μm to about 230 μm. The thermal radiation post and the thermal conductive pattern 520 may respectively have a second height H2 in the third direction D3 and a third height H3 in the third direction D3. In an embodiment, the second height H2 may range from about 100 μm to about 150 μm, and the third height H3 may range from about 60 μm to about 80 μm. The thermal radiation post 510 may include, for example, copper (Cu). The thermal conductive pattern 520 may include a thermal interface material (TIM). The thermal conductive pattern 520 may include, for example, at least one selected from aluminum (Al), aluminum oxide (Al₂O₃), aluminum nitride (AlN), magnesium oxide (MgO), silicon carbide (SiC), and silicon (Si).

As shown in FIG. 2, the third semiconductor chip 300 may be disposed on the first semiconductor chip 100, the second semiconductor chip 200, and the thermal radiation structure 500. For example, the thermal radiation structure 500 may be disposed below the third semiconductor chip 300. One part of a bottom surface of the third semiconductor chip 300 may be in contact with the top surface of the first semiconductor chip 100. Another part of the bottom surface of the third semiconductor chip 300 may be in contact with the top surface of the second semiconductor chip 200. For example, the third semiconductor chip 300 may include third connection pads 301 disposed on the bottom surface of the third semiconductor chip 300. In an embodiment, the third connection pad 301 and the first connection pad 170 may be hybrid-bonded to and in contact with each other. In an embodiment, the third connection pad 301 and the second connection pad 270 may be hybrid-bonded to and in contact with each other. In the disclosure, the term “hybrid bonding” may denote a bonding in which two components of the same kind are merged at an interface therebetween. One of the third connection pads 301 may have a bottom surface in contact with a top surface of the first connection pad 170. In an embodiment, one of the third connection pads 301 may have a bottom surface in contact with a top surface of the second connection pad 270.

The third semiconductor chip 300 may include a third wiring layer 310, a third semiconductor substrate 330, and a first circuit layer 320 (between the third wiring layer 310 and the third semiconductor substrate 330). In an embodiment, the third semiconductor substrate 330 may be disposed farther than the third wiring layer 310 from the first redistribution substrate 400. The third semiconductor substrate 330 may be, for example, a silicon substrate. The third wiring layer 310 and the first circuit layer 320 will be further discussed below.

For example, the third semiconductor chip 300 may be a logic chip. For example, the third semiconductor chip 300 may be one of a central processing unit (CPU), a graphic processing unit (GPU), and an application specific integrated circuit (ASIC).

As shown in FIG. 2, a first molding layer MD1 may be disposed on the top surface of the first redistribution substrate 400. On the top surface of the first redistribution substrate 400, the first molding layer MD1 may fill an area between the thermal radiation structure 500 and the first semiconductor chip 100 and an area between the thermal radiation structure 500 and the second semiconductor chip 200. The first molding layer MD1 may include a dielectric material that may include either a material such as an epoxy molding compound (EMC) or an adhesive material.

A second redistribution substrate 600 may be disposed on the first molding layer MD1. For example, the second redistribution substrate 600 may be disposed on an upper portion of the third semiconductor chip 300. The second redistribution substrate 600 may include second dielectric layers 610 and second redistribution patterns 611. A bottom surface of the second redistribution substrate 600 may be spaced apart in the third direction D3 from a top surface of the thermal radiation structure 500.

As shown in FIG. 2, a conductive pillar 550 may penetrate the first molding layer MD1 to reside between the first redistribution substrate 400 and the second redistribution substrate 600. The conductive pillar 550 may be spaced apart, in the first direction D1 and/or the second direction D2, from the first semiconductor chip 100 and the second semiconductor chip 200. The conductive pillar 550 may be in contact with the third redistribution pad 411c and the second redistribution pattern 611. For example, the conductive pillar 550 may be electrically connected to the third redistribution pad 411c and the second redistribution pattern 611. In an embodiment, the first height H1 of the thermal radiation structure 500 may be less than a height in the third direction D3 of the conductive pillar 550. The conductive pillar 550 may include metal, such as copper (Cu).

Referring to FIGS. 2 and 3, the third wiring layer 310 and the first circuit layer 320 of the third semiconductor chip 300 may be disposed on the thermal conductive pattern 520 of the thermal radiation structure 500. The third wiring layer 310 of the third semiconductor chip 300 may include a fourth dielectric layer 305 and third wiring lines 308 disposed in the fourth dielectric layer 305. The fourth dielectric layer 305 may include a dielectric material, such as oxide (e.g., SiO2). The third wiring lines 308 may include metal, such as copper (Cu) or aluminum (Al). On a lower portion of the third wiring layer 310, at least one of the third wiring lines 308 may be in contact with the thermal conductive pattern 520.

The first circuit layer 320 may be disposed on the third wiring layer 310. The first circuit layer 320 may include (a plurality of) transistors TR. At least one of the transistors TR may include a source, a drain, and a gate. For example, the transistors TR may perform a function of processing data through logic operations and control signal processing within the third semiconductor chip 300. The first circuit layer 320 may include a first circuit region RE1 and a second circuit region RE2. At least one of the first and second circuit regions RE1 and RE2 may include one or more transistors TR. The thermal radiation structure 500 may overlap, in the third direction D3, with the first circuit region RE1 and the second circuit region RE2.

The number and configuration of the transistors TR include in the first and second circuit regions RE1 and RE2 may be variously changed in accordance with placement and design. For example, in another embodiment, which is different from the embodiment shown in FIG. 3, the first circuit layer 320 may include three or more circuit regions. The thermal radiation structure 500 may overlap in the third direction D3 with at least one circuit region.

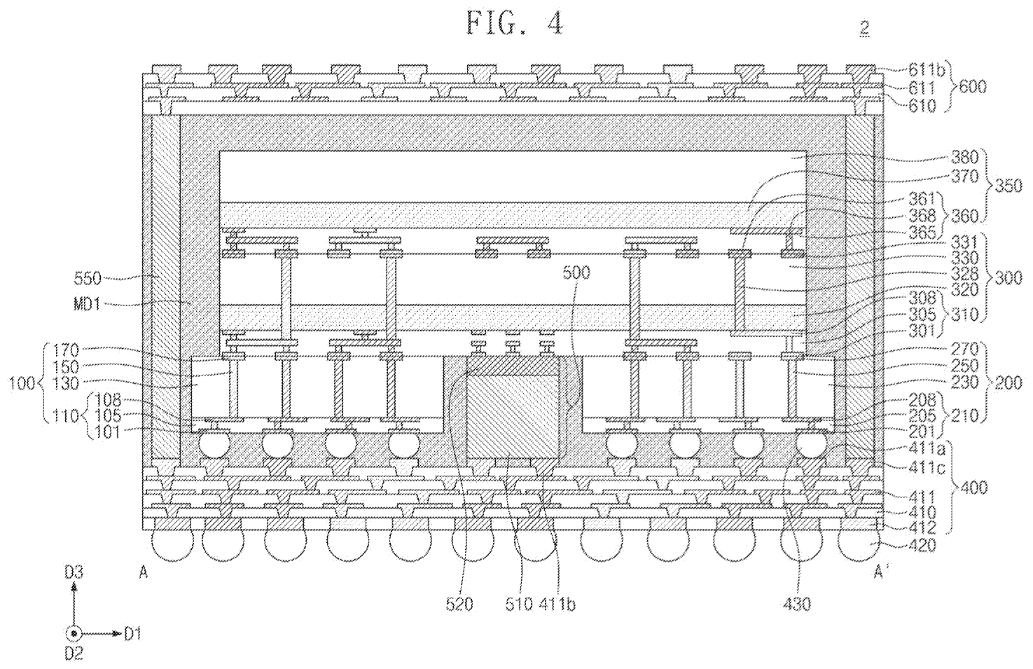

FIG. 4 illustrates a cross-sectional view showing a semiconductor package 2 according to some embodiments of the disclosure. Omission will be made to avoid the explanation of that discussed in FIGS. 1 to 3.

Referring to FIG. 4, a fourth semiconductor chip 350 may be disposed on the third semiconductor chip 300. A bottom surface of the fourth semiconductor chip 350 may be in contact with a top surface of the third semiconductor chip 300. For example, the fourth semiconductor chip 350 may include fifth connection pads 361 disposed on the bottom surface of the fourth semiconductor chip 350. The third semiconductor chip 300 may be provided with fourth connection pads 331 disposed on the top surface thereof, and the fourth connection pad 331 and the fifth connection pad 361 may be hybrid-bonded to and in contact with each other. A bottom surface of each of the fifth connection pads 361 may be in contact with a top surface of the fourth connection pad 331 disposed on the top surface of the third semiconductor chip 300. The third semiconductor chip 300 may include a through via 328 that penetrates the third semiconductor substrate 330, the first circuit layer 320, and the fourth dielectric layer 305. The third through via 328 may connect the third wiring line 308 and the fifth connection pad 361 to each other.

The fourth semiconductor chip 350 may include a fourth wiring layer 360, a fourth semiconductor substrate 380, and a second circuit layer 370 disposed between the fourth wiring layer 360 and the fourth semiconductor substrate 380. The fourth semiconductor substrate 380 may be disposed farther than the fourth wiring layer 360 from the first redistribution substrate 400. The fourth wiring layer 360 may include a fifth dielectric layer 365 and fourth wiring lines 368 disposed in the fifth dielectric layer 365. The fourth wiring lines 368 may include metal, such as copper or aluminum. The fourth semiconductor substrate 380 may be, for example, a silicon substrate. The fourth semiconductor chip 350 may be of a different type from the third semiconductor chip 300. The fourth semiconductor chip 350 may be, for example, a static random access memory (SRAM).

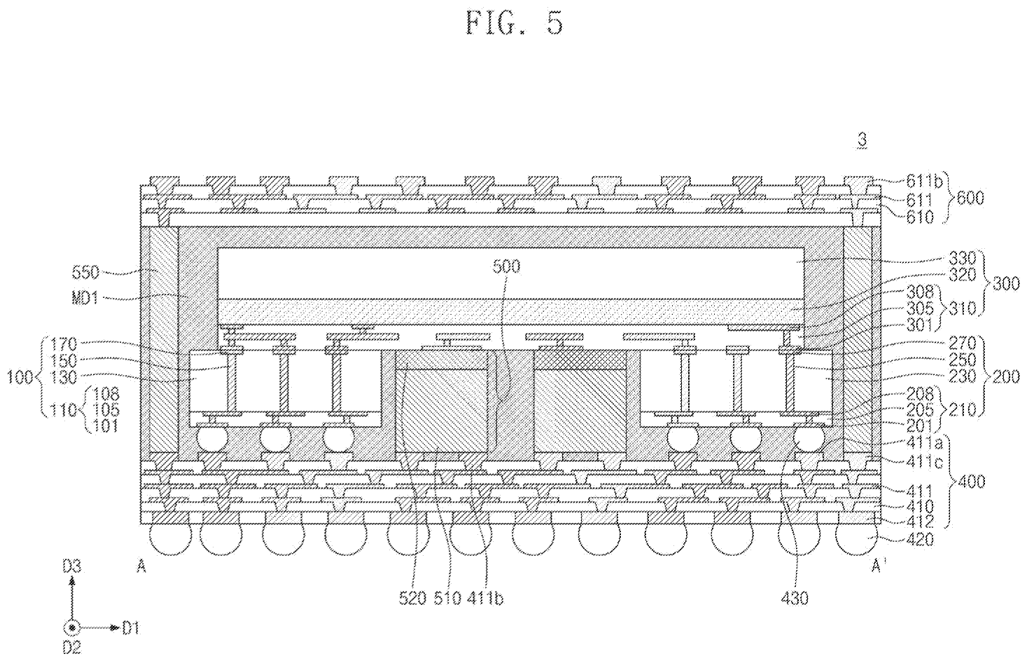

FIG. 5 illustrates a cross-sectional view showing a semiconductor package 3 according to some embodiments of the disclosure. Omission will be made to avoid the explanation of that discussed in FIGS. 1 to 3.

Referring to FIG. 5, the thermal radiation structure 500 may correspond to two thermal radiation structures 500 provided on the top surface of the first redistribution substrate 400. For example, those two thermal radiation structures 500 may be spaced apart from each other in the first direction D1 between the first semiconductor chip 100 and the second semiconductor chip 200. FIG. 5 illustrates the two thermal radiation structures 500, but, in some embodiments, the number and arrangement of the thermal radiation structure 500 may be variously changed. Embodiments of the disclosure are not limited to the embodiment shown in FIG. 5. Referring together to FIGS. 3 and 5, the number and arrangement of the thermal radiation structure 500 may be variously changed in accordance with a design and arrangement of a plurality of circuit regions included in the first circuit layer 320. For example, a plurality of thermal radiation structures 500 may be disposed to overlap in the third direction D3 with circuit regions from which a large amount of heat is generated.

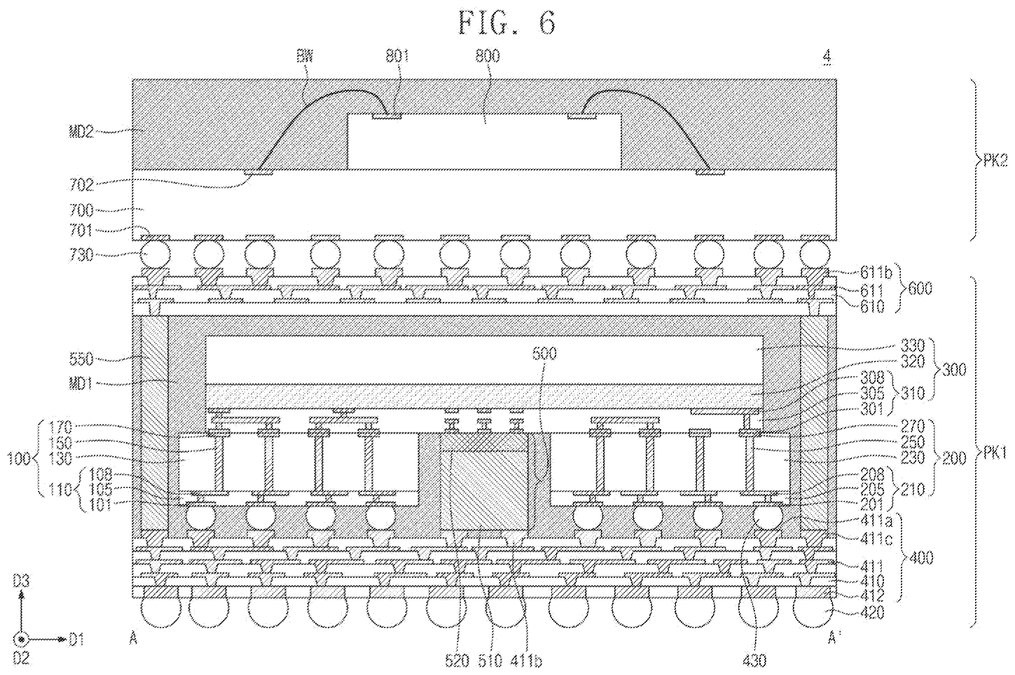

FIG. 6 illustrates a cross-sectional view showing a semiconductor package 4 according to some embodiments of the disclosure. Omission will be made to avoid the explanation of that discussed in FIGS. 1 to 3.

Referring to FIG. 6, the semiconductor package 4 according some embodiments may include a first semiconductor package PK1 and a second semiconductor package PK2 on the first semiconductor package PK1. For example, the semiconductor package 4 shown in FIG. 6 may have a package-on-package structure. The first semiconductor package PK1 may be the same as the semiconductor package 1 discussed in FIG. 2. The second semiconductor package PK2 may include a package substrate 700, a fifth semiconductor chip 800, and a second molding layer MD2.

The package substrate 700 may be disposed on the second redistribution substrate 600. The package substrate 700 may be, for example, a printed circuit board (PCB). Alternatively, the package substrate 700 may have a structure in which at least one dielectric layer and at least one wiring layer are alternately stacked.

The package substrate 700 may include a plurality of first package substrate pads 702 on a top surface of the package substrate 700 and a plurality of second package substrate pads 701 on a bottom surface of the package substrate 700.

The fifth semiconductor chip 800 may be disposed on the package substrate 700. For example, the fifth semiconductor chip 800 may be a memory chip. For example, the fifth semiconductor chip 800 may be one of dynamic random access memory (DRAM), static random access memory (SRAM), and NAND Flash memory.

A third chip pad 801 disposed on one surface of the fifth semiconductor chip 800 may be connected through a bonding wire BW to the first package substrate pad 702 of the package substrate 700.

The second molding layer MD2 may be disposed on the package substrate 700. The second molding layer MD2 may cover the top surface of the package substrate 700 and lateral and top surfaces of the fifth semiconductor chip 800. The second molding layer MD2 may include a material substantially the same as or similar to that of the first molding layer MD1.

A package connection terminal 730 may be disposed between the package substrate 700 and the second redistribution substrate 600. For example, the package connection terminal 730 may be attached to the second redistribution pads 611b and in contact with the second package substrate pads 701. The package connection terminal 730 may electrically connect the fifth semiconductor chip 800 to the first semiconductor chip 100, the second semiconductor chip 200, and the third semiconductor chip 300. The package connection terminal 730 may include a metallic material substantially the same as or similar to that of the external connection terminals 420. For example, the package connection terminal 730 may include tin (Sn), bismuth (Bi), lead (Pb), silver (Ag), or any alloy thereof.

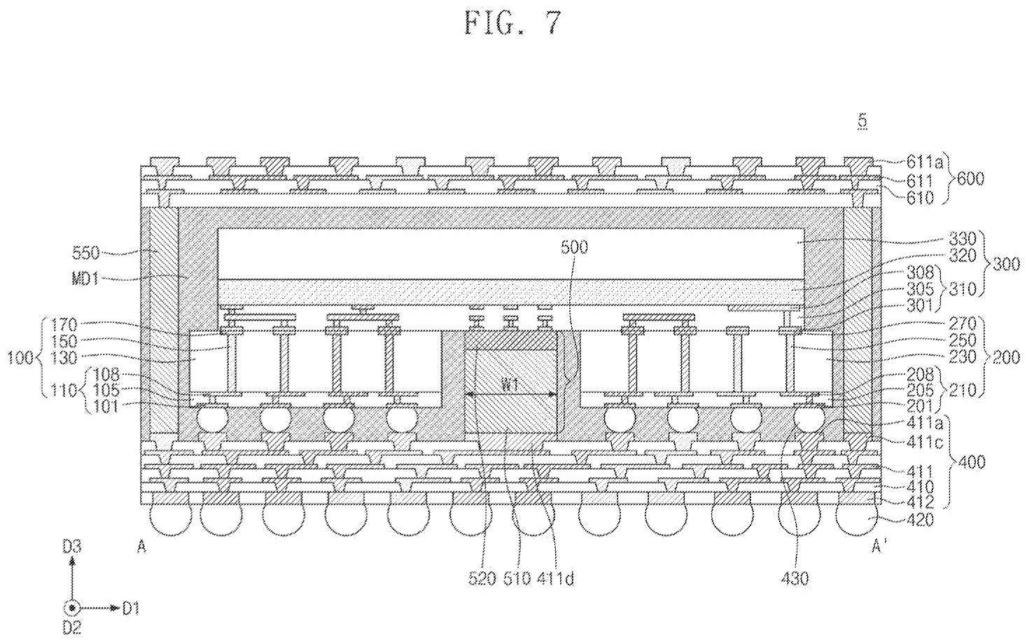

FIG. 7 illustrates a cross-sectional view showing a semiconductor package 5 according to some embodiments of the disclosure. Elements already discussed with respect to FIGS. 1 to 3 are omitted.

Referring to FIG. 7, the thermal radiation structure 500 may be provided on a fourth redistribution pad 411d. In this case, the bottom surface of the thermal radiation structure 500 may be in contact with a top surface of the fourth redistribution pad 411d. In an embodiment, a length in the first direction D1 of the fourth redistribution pad 411d may be substantially the same as the first width W1 of the thermal radiation structure 500. In an embodiment, the length in the first direction D1 of the fourth redistribution pad 411d may be greater than a length in the first direction D1 of the second redistribution pad 411b shown in FIG. 2.

In the related art, lower semiconductor chips of a semiconductor package may impede discharge of heat from an upper semiconductor chip in a hybrid bonding structure of semiconductor chips. For example, when the upper semiconductor chip is a logic chip, because the upper semiconductor chip performs logic operations and control signal processing, an amount of heat generated from the upper semiconductor chip may be greater than an amount of heat generated from the lower semiconductor chips, with the result that the semiconductor chips may decrease in lifetime and the semiconductor package may deteriorate in performance.

In contrast to the related art, semiconductor packages according to some embodiments of the disclosure may include the first semiconductor chip 100, the second semiconductor chip 200, the third semiconductor chip 300, and the thermal radiation structure 500. The thermal radiation structure 500 may be disposed between the first semiconductor chip 100 and the second semiconductor chip 200, and the third semiconductor chip 300 may be disposed on the first semiconductor chip 100, the second semiconductor chip 200, and the thermal radiation structure 500. In this case, one or more of a plurality of circuit regions included in the third semiconductor chip 300 may vertically overlap the thermal radiation structure 500. As a result, heat generated from the circuit regions may be promptly discharged downwards through the thermal radiation structure 500. In addition, as the number and arrangement of the thermal radiation structure 500 are variously changed in accordance with a design and arrangement of the circuit regions included in the third semiconductor chip 300, the semiconductor packages may have maximum thermal radiation properties.

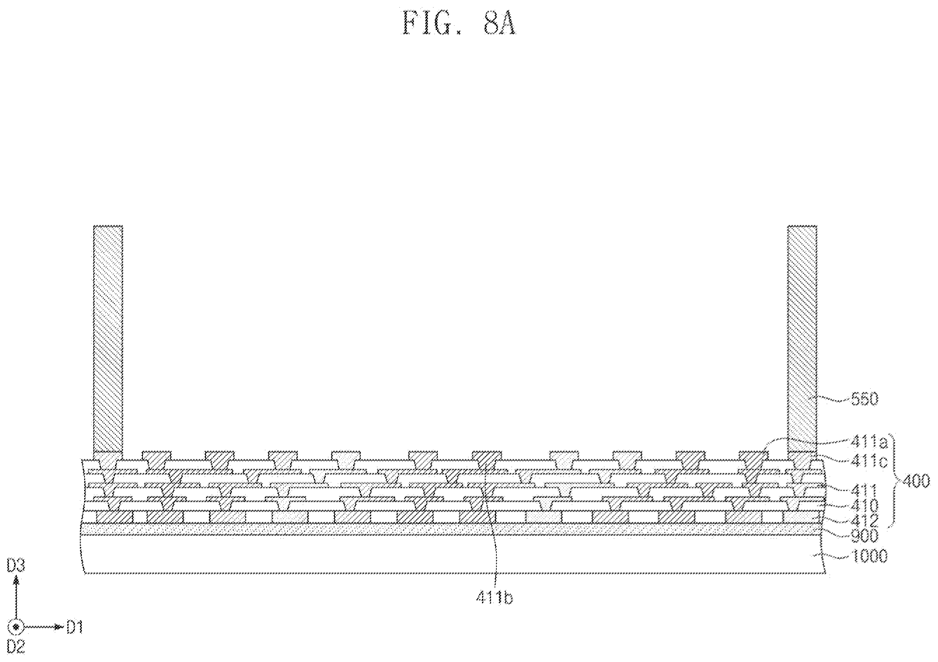

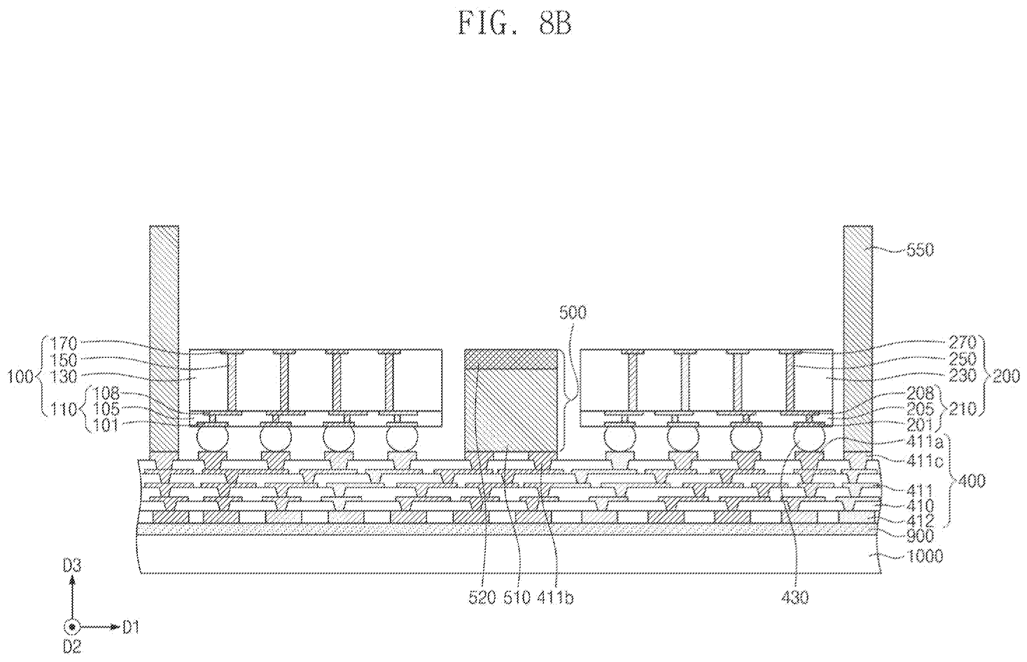

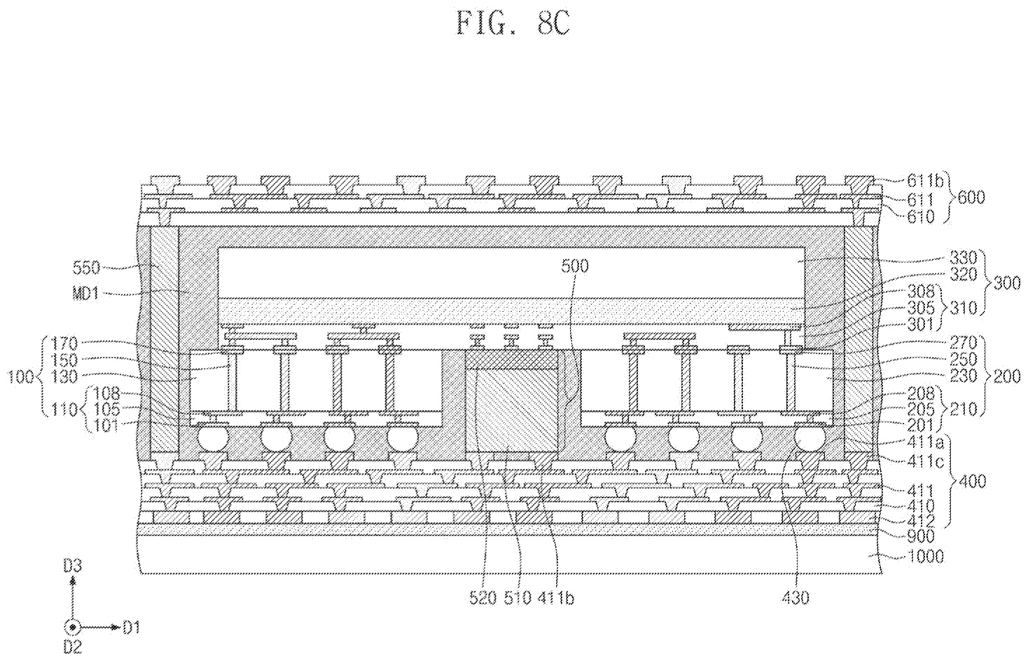

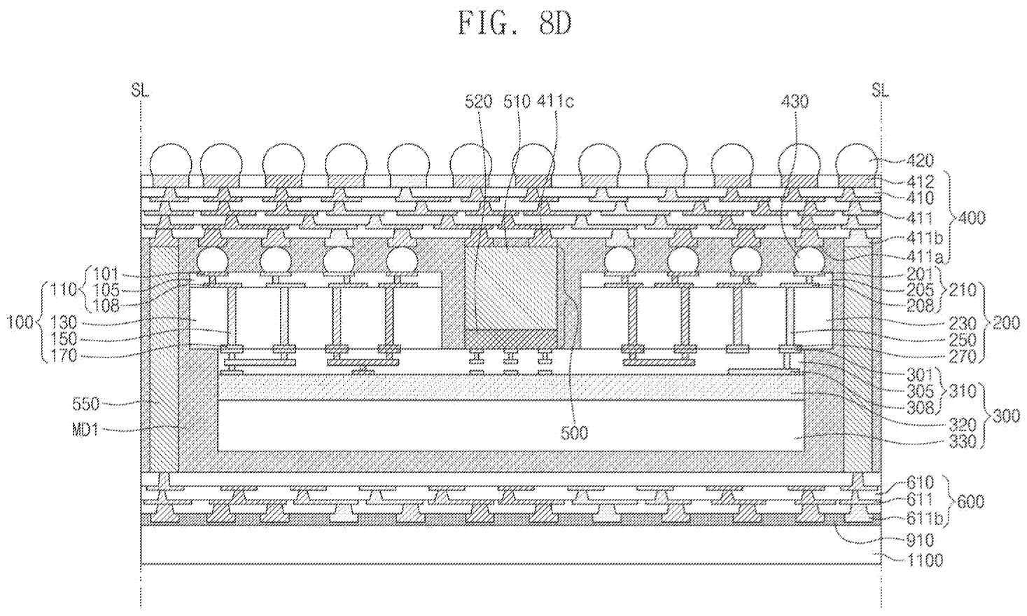

FIGS. 8A to 8D illustrate cross-sectional views showing a method of fabricating a semiconductor device according to some embodiments of the disclosure. For example, FIGS. 8A to 8D illustrate cross-sectional views showing the semiconductor package 1 illustrated in FIG. 2.

Referring to FIG. 8A, a first carrier substrate 1000 may be provided, and a first adhesive member 900 may be provided on the first carrier substrate 1000. The first carrier substrate 1000 may be a dielectric substrate including glass or polymer, or may be a conductive substrate including metal. The first adhesive member 900 may include a glue tape.

A first redistribution substrate 400 may be formed on the first adhesive member 900. The first redistribution substrate 400 may include a first dielectric layer 410 and first redistribution patterns 411.

The first dielectric layer 410 may be formed by coating, on the first adhesive member 900, an organic material such as a photo-imageable dielectric (PID). The formation of the first redistribution patterns 411 may include patterning the first dielectric layer 410 to form openings, forming a seed layer within the opening and on a top surface of the first dielectric layer 410, forming on the seed layer a mask that defines an area where a conductive pattern will be formed, using the seed layer as an electrode to perform an electroplating process to form the conductive pattern, removing the mask, and using the conductive pattern as an etching mask to pattern the seed layer.

The formation of the first dielectric layer 410, the formation of the seed layer, and the formation of the first redistribution patterns 411 may be repeatedly performed. Therefore, a first redistribution substrate 400 may be constituted by stacked first dielectric layers 410 and stacked first redistribution patterns 411.

Afterwards, a conductive pillar 550 may be formed on the third redistribution pad 411c included in the first redistribution substrate 400.

Referring to FIG. 8B, a first semiconductor chip 100, a second semiconductor chip 200, a thermal radiation structure 500 may be mounted on the first redistribution substrate 400. The mounting of the thermal radiation structure 500 may include allowing a bottom surface of the thermal radiation structure 500 to contact a top surface of the third redistribution pad 411c. According to some embodiments, an adhesive material may be coated on the top surface of the third redistribution pad 411c to stably mount the thermal radiation structure 500 on the first redistribution substrate 400. The first semiconductor chip 100 and the second semiconductor chip 200 may be mounted spaced apart in the first direction D1 from the thermal radiation structure 500.

Referring to FIG. 8C, a third semiconductor chip 300 may be provided on and in contact with the first semiconductor chip 100, the second semiconductor chip 200, and the thermal radiation structure 500. For example, the thermal radiation structure 500 may be disposed below the third semiconductor chip 300.

A first molding layer MD1 may be formed on a top surface of the first redistribution substrate 400. On the top surface of the first redistribution substrate 400, the first molding layer MD1 may be formed to cover an area between the first semiconductor chip 100 and the thermal radiation structure 500, an area between the second semiconductor chip 200 and the thermal radiation structure 500, and lateral and top surfaces of the third semiconductor chip 300. Thereafter, a second redistribution substrate 600 may be formed on the first molding layer MD1.

Referring to FIG. 8D, a second adhesive member 910 and a second carrier substrate 1100 may be provided on the second redistribution substrate 600. After that, the first redistribution substrate 400 and the second redistribution substrate 600 may be turned upside down, and then the first carrier substrate 1000 and the first adhesive member 900 may be removed from the first redistribution substrate 400. The removal of the first carrier substrate 1000 and the first adhesive member 900 may expose an under-bump pattern 412. An external connection terminal 420 may be formed on the under-bump pattern 412.

The first redistribution substrate 400, the second redistribution substrate 600, and the first molding layer MD1 may undergo a sawing process along a sawing line SL. The sawing process may form a plurality of semiconductor packages 1 according to some embodiments of the disclosure depicted in FIG. 2.

After that, the first redistribution substrate 400 and the second redistribution substrate 600 may be turned upside down again, and then the second carrier substrate 1100 and the second adhesive member 910 may be removed from the second redistribution substrate 600.

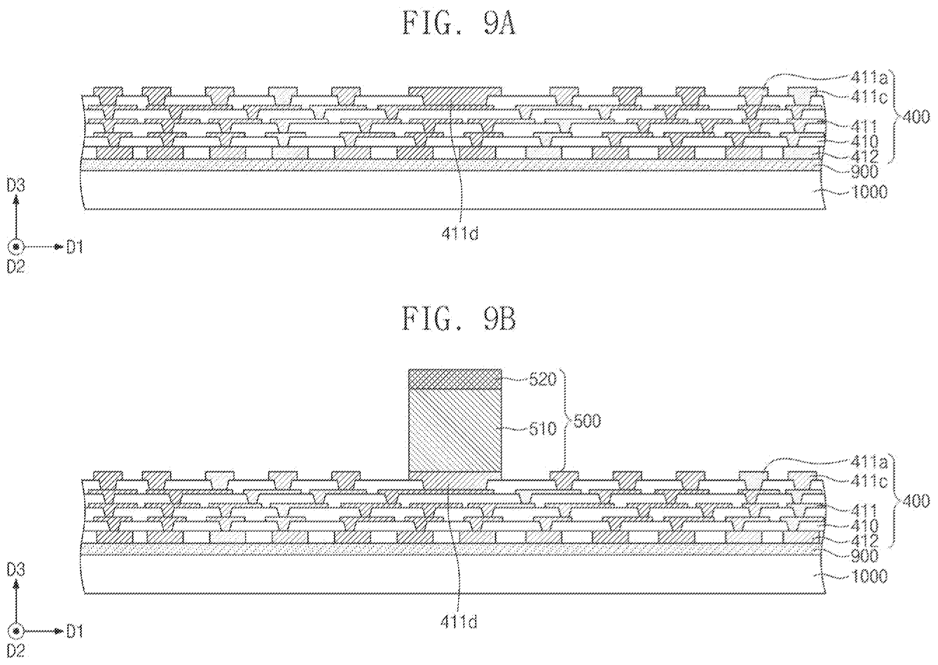

FIGS. 9A and 9B illustrate cross-sectional views partially showing a method of fabricating a semiconductor package according to some embodiments of the disclosure. For example, FIGS. 9A and 9B depict cross-sectional views partially showing the semiconductor package 5 illustrated in FIG. 7.

Referring to FIG. 9A, a first redistribution substrate 400 may be formed on the first adhesive member 900. The first redistribution substrate 400 may be formed to include a fourth redistribution pad 411d whose length in the first direction D1 is greater than a length in the first direction D1 of at least one of the first redistribution pad 411a and the third redistribution pad 411c.

Referring to FIG. 9B, a thermal radiation post 510 may be formed on the fourth redistribution pad 411d. The formation of the thermal radiation post 510 may include forming on the fourth redistribution pad 411d a mask that defines an area where the thermal radiation post 510 will be formed, using the fourth redistribution pad 411d as an electrode to perform an electroplating process to form the thermal radiation post 510, and removing the mask. A thermal conductive pattern 520 may be formed on the thermal radiation post 510.

Afterwards, in an embodiment, the first redistribution substrate 400 may undergo a process similar to that discussed in FIGS. 8B to 8D to eventually fabricate the semiconductor package 5 depicted in FIG. 7.

A semiconductor package according to some embodiments of the disclosure may include a first semiconductor chip, a second semiconductor chip, and a third semiconductor chip, and a thermal radiation structure. The thermal radiation structure may be disposed between the first semiconductor chip and the second semiconductor chip. The third semiconductor chip may be disposed on the first semiconductor chip, the second semiconductor chip, and the thermal radiation structure. In this case, one or more of a plurality of circuit regions included in the third semiconductor chip may vertically overlap the thermal radiation structure, and the thermal radiation structure may contact a substrate. As a result, heat generated from the circuit regions may be promptly discharged through the thermal radiation structure to the substrate. In addition, as the number and arrangement of the thermal radiation structure are variously changed in accordance with a design and arrangement of the circuit regions included in the third semiconductor chip, the semiconductor packages may have maximum thermal radiation properties.

The aforementioned description provides some embodiments for explaining the disclosure. Therefore, the disclosure are not limited to the embodiments described above. It will be understood by one of ordinary skill in the art that variations in form and detail may be made therein without departing from the spirit and features of the disclosure.

What is claimed is:

1. A semiconductor package comprising:
a first substrate;
a first semiconductor chip on the first substrate;
a second semiconductor chip on the first substrate, the second semiconductor chip being spaced apart, in a first direction, from the first substrate, the first direction being parallel to a top surface of the first substrate;
at least one thermal radiation structure on the first substrate and between the first semiconductor chip and the second semiconductor chip; and
a third semiconductor chip on the first semiconductor chip, the second semiconductor chip, and the at least one thermal radiation structure,
wherein the at least one thermal radiation structure comprises:
a thermal radiation post; and
a thermal conductive pattern on the thermal radiation post,
wherein a bottom surface of the third semiconductor chip is in contact with the thermal conductive pattern, and
wherein the top surface of the first substrate is in contact with the thermal radiation post.

2. The semiconductor package of claim 1, wherein the at least one thermal radiation structure has a first width in the first direction, and
wherein the first width is in a range of about 150 μm to about 250 μm.

3. The semiconductor package of claim 1, wherein the at least one thermal radiation structure has a first height in a second direction perpendicular to the top surface of the first substrate,
wherein the first height is in a range of about 160 μm to about 230 μm.

4. The semiconductor package of claim 3, wherein the thermal radiation post has a second height in the second direction,
wherein the thermal conductive pattern has a third height in the second direction,
wherein the second height is in a range of about 100 μm to about 150 μm, and
wherein the third height is in a range of about 60 μm to about 80 μm.

5. The semiconductor package of claim 1, wherein a portion of the bottom surface of the third semiconductor chip is in contact with a portion of a top surface of the first semiconductor chip and a portion of a top surface of the second semiconductor chip.

6. The semiconductor package of claim 1, wherein the first substrate comprises an upper pad on an upper portion of the first substrate,
wherein a top surface of the upper pad protrudes from the top surface of the first substrate, and
wherein a bottom surface of the thermal radiation post is in contact with the top surface of the upper pad.

7. The semiconductor package of claim 1, wherein the third semiconductor chip is a logic chip.

8. The semiconductor package of claim 3, further comprising a second substrate above the first substrate,
wherein the second substrate is above the third semiconductor chip, and
wherein the at least one thermal radiation structure is spaced apart, in the second direction, from the second substrate.

9. The semiconductor package of claim 8, further comprising:
a molding layer on the first substrate; and
a conductive pillar that penetrates the molding layer and that electrically connects the first substrate with the second substrate.

10. The semiconductor package of claim 9, wherein the molding layer fills a first area between the at least one thermal radiation structure and the first semiconductor chip and a second area between the at least one thermal radiation structure and the second semiconductor chip, and
wherein the first height, in the second direction, of the at least one thermal radiation structure is less than a second height, in the second direction, of the conductive pillar.

11. The semiconductor package of claim 1, wherein the at least one thermal radiation structure corresponds to two thermal radiation structures, and
wherein the two thermal radiation structures are spaced apart from each other, in the first direction, between the first semiconductor chip and the second semiconductor chip.

12. The semiconductor package of claim 1, wherein the thermal radiation post comprises copper.

13. The semiconductor package of claim 1, wherein the thermal conductive pattern comprises at least one of aluminum (Al), aluminum oxide (Al₂O₃), aluminum nitride (AlN), magnesium oxide (MgO), silicon carbide (SiC), and silicon (Si).

14. A semiconductor package comprising:
a first substrate;
a first semiconductor chip on the first substrate;
a second semiconductor chip on the first substrate, the second semiconductor chip being spaced apart in a first direction from the first semiconductor chip, the first direction being parallel to a top surface of the first substrate;
at least one thermal radiation structure on the first substrate and between the first semiconductor chip and the second semiconductor chip; and
a third semiconductor chip on the first semiconductor chip, the second semiconductor chip, and the at least one thermal radiation structure,
wherein the at least one thermal radiation structure comprises:
a thermal radiation post; and
a thermal conductive pattern on the thermal radiation post,
wherein the third semiconductor chip comprises:
a wiring layer; and
a circuit layer on the wiring layer,
wherein the thermal conductive pattern is in contact with the wiring layer,
wherein the circuit layer comprises a plurality of circuit regions, and
wherein the at least one thermal radiation structure overlaps, in a second direction, with at least one of the plurality of circuit regions, the second direction being perpendicular to the top surface of the first substrate.

15. The semiconductor package of claim 14, further comprising a fourth semiconductor chip on the third semiconductor chip,
wherein the third semiconductor chip is a logic chip, and
wherein the fourth semiconductor chip is a static random access memory (SRAM).

16. The semiconductor package of claim 14, wherein at least one of the first semiconductor chip and the second semiconductor chip is a mobile chip or an analog chip.

17. The semiconductor package of claim 14, further comprising a second substrate above the first substrate,
wherein the second substrate is above the third semiconductor chip, and
wherein the at least one thermal radiation structure is spaced apart, in the second direction, from the second substrate.

18. The semiconductor package of claim 17, further comprising:
a package substrate on the second substrate; and
a fifth semiconductor chip on the package substrate,
wherein the fifth semiconductor chip is a memory chip.

19. A semiconductor package comprising:
a first redistribution substrate;
a second redistribution substrate on the first redistribution substrate;
a first semiconductor chip on the first redistribution substrate;
a second semiconductor chip on the first redistribution substrate, the second semiconductor chip being spaced apart, in a first direction, from the first semiconductor chip, the first direction being parallel to a top surface of the first redistribution substrate;
a third semiconductor chip on the first semiconductor chip and the second semiconductor chip, a portion of a bottom surface of the third semiconductor chip being in contact with a portion of a top surface of the first semiconductor chip and a portion of a top surface of the second semiconductor chip; and
at least one thermal radiation structure below the third semiconductor chip, the at least one thermal radiation structure being between the first semiconductor chip and the second semiconductor chip,
wherein the third semiconductor chip comprises:
a wiring layer; and
a circuit layer on the wiring layer,
wherein the at least one thermal radiation structure comprises:
a thermal radiation post; and
a thermal conductive pattern on the thermal radiation post,
wherein the thermal conductive pattern is in contact with the wiring layer,
wherein the circuit layer comprises a plurality of circuit regions, and
wherein the at least one thermal radiation structure overlaps, in a second direction, with at least one of the plurality of circuit regions, the second direction being perpendicular to the top surface of the first redistribution substrate.

20. The semiconductor package of claim 19, further comprising:
a molding layer on the first redistribution substrate; and
a conductive pillar that penetrates the molding layer and electrically connects the first redistribution substrate with the second redistribution substrate,
wherein the molding layer fills a first area between the at least one thermal radiation structure and the first semiconductor chip and a second area between the at least one thermal radiation structure and the second semiconductor chip, and
wherein a first height in the second direction of the at least one thermal radiation structure is less than a second height in the second direction of the conductive pillar.
